(19) United States
(12) Patent Application Publication
(10) Pub. No.: US 2007/0231598 A1
(43) Pub. Date: Oct. 4, 2007

(54) Electroluminescent Polymers

(75) Inventors: Arne Busing, Frankfurt/Main (DE); Rene Scheurich, Gross-Zimmern (DE); Susanne Heun, Bad Soden (DE); Ingrid Bach, Hofheim (DE)

Correspondence Address: CONNOLLY BOVE LODGE & HUTZ, LLP, P O BOX 2207, WILMINGTON, DE, 19899, US

(73) Assignee: Merck Patent GmbH Patent & Scientific Information, Carmstadt (DE)

(21) Appl. No.: 11/596,281

(22) PCT Filed: May 10, 2005
(86) PCT No.: PCT/EP05/05020

§ 371 Date: Nov. 13, 2006

(30) Foreign Application Priority Data
May 11, 2004 (DE) 10 2004 023 278.4

(51) Int. Cl. C08G 73/00; C07F 7/00; C07F 7/08; C09K 11/00; H01L 51/00; H01L 51/30; C09K 11/06; C08G 61/00; C08G 61/12

(52) U.S. Cl. 428/690; 252/519.21; 528/4; 528/5; 528/9

(57) ABSTRACT

The invention relates to copolymers that comprise the structural units according to formula (1) and iridium complexes as triplet emissives. The inventive polymers are better suited to the use in organic light-emitting diodes than comparable prior art materials.

Broadly based research on the commercialisation of display and illumination elements based on polymeric (organic) light-emitting diodes (PLEDs) has been under way for about 13 years. This development was initiated by the basic developments disclosed in WO 90/13148. A first product in the form of a relatively small display (in a razor from PHILIPS N.V.) has also been commercially available since recently.

A development which has been evident for a few years, in particular in the area of “small molecule” displays, is the use of materials which are able to emit light from the triplet state and thus exhibit phosphorescence instead of fluorescence (M. A. Baldo et al., Appl. Phys. Lett. 1999, 75, 4-6), enabling an up to four-fold energy and power efficiency. Essential conditions which may be mentioned for practical usability here are, in particular, efficient energy transfer from the matrix to the triplet emitter (and consequently efficient light emission), a long operating lifetime and a low operating voltage.

Recently, there have increasingly been efforts to utilise the advantages of vapour-depositable triplet emitters for polymer applications too. Thus, so-called hybrid device structures have been considered, which combine the advantages of “small-molecule” OLEDs with those of polymeric OLEDs (=PLEDs) and are formed by mixing the triplet emitter into the polymer. However, it is more advantageous to incorporate the triplet emitter and a suitable matrix into a polymer, since this avoids the risk of phase separation during device production and operation. Both methods have the advantage that the compounds can be processed from solution and that an expensive and complex vapour-deposition process, as for devices based on low-molecular-weight compounds, is not necessary. Application from solution (for example by high-resolution printing processes) will have significant advantages in the long term compared with the vacuum evaporation process which is common today, especially with respect to scalability, structurability, coating efficiency and economy.

A suitable matrix material which facilitates efficient energy transfer to the triplet emitter and, in combination with this good lifetime, has low operating voltages is also necessary here.

In spite of the advances achieved recently, there is still considerable potential for improvement for corresponding materials in the area of polymeric triplet emitters. A clear need for improvement is furthermore to be seen, inter alia, in the following fields:
(1) The efficiency of the electroluminescent elements must be improved further. The fact that higher efficiency is possible in principle is shown by the results of electroluminescent elements based on small molecules.
(2) The operating voltage of the electroluminescent elements is still too high for high-quality electronic applications.
(3) In general, it has hitherto been necessary to optimise the matrix materials for certain triplet emitters, so that although a matrix material may exhibit good results with one triplet emitter, it produces, however, significantly poorer results with another triplet emitter, even for a comparable colour and in particular in the case of different emission colours. It would be desirable here to have available a matrix material which exhibits good results with a wide range of triplet emitters.

It is thus apparent that there continues to be a great need for improvement in the area of polymer-bonded triplet emitters and corresponding suitable matrix materials.

N. S. Baek et al. (Thin Solid Films 2002, 417, 111) describe ruthenium-containing organosilane polymers as red-emitting materials. However, the intensity of the red bands at room temperature is only weak due to non-radiant relaxation. Even at low temperatures, which are prohibitive for conventional use of OLEDs, higher intensities were measured. These materials are thus apparently not suitable for use in PLEDs, since a high luminescence quantum yield is necessary therein, even at room temperature, for good efficiency. This suggests that the combination of ruthenium complexes with organosilanes is possibly not suitable for efficient emission. A similar result is described with platinum(II)-containing silylacetylene polymers (W.-Y. Wong et al., J. Chem. Soc., Dalton Trans. 2002, 1587). Here, an efficient blue-green phosphorescence is observed at low temperature, while the triplet exciton is quenched at room temperature by thermally activated diffusion. These platinum/silylacetylene polymers are thus also apparently not suitable for efficient emission at room temperature and are therefore also not suitable for use in OLEDs.

WO 03/092334 describes polysilanes which contain covalently bonded triplet emitters and are also claimed to be suitable for efficient blue emission. However, absolutely no device examples are given, and it must consequently be assumed that these copolymers do not solve the problem and are possibly not suitable for other emission colours either. Furthermore, these polymers are not unproblematical since reaction with metallic sodium is necessary for the synthesis (Wurtz synthesis), which represents a safety risk, in particular in industrial production, and can thus only be used with difficulty on a relatively large scale.

Surprisingly, it has been found that—hitherto unknown—copolymers which contain certain covalently bonded organosilane units and emitting iridium complexes have significant improvements compared with polymers and mixtures in accordance with the prior art, in particular high emission efficiency and low operating voltages. This is particularly surprising since organosilane polymers comprising other emitting metals (ruthenium, platinum), as described above, only result in a low phosphorescence quantum yield at room temperature. In addition, it is surprising that the same polymer matrix exhibits good results here both for green and also for red triplet emitters. It is a significant technological advantage to be able to use a matrix for a plurality of or ideally all emission colours without having to optimise a separate matrix for each individual emitter. The present application therefore relates to these copolymers and to the use thereof in organic electronic devices.

The invention relates to copolymers containing
(A) 1-99.99% of at least one structural unit of the formula (1) 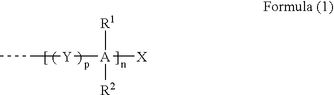
   where the following applies to the symbols and indices used:
   A is on each occurrence, identically or differently, Si, Ge, Sn or Pb;
   Y is on each occurrence, identically or differently, a divalent aromatic or heteroaromatic ring system having 1 to 40 C atoms, which may be substituted by one or more radicals R⁴, a vinylene group —CR⁴═CR⁴— or an acetylene group —C≡C—;
   X is on each occurrence, identically or differently, a divalent group —(Y)ₚ— (and thus has a further link to the polymer chain) or a mono-valent group R³;
   R¹, R², R³ is on each occurrence, identically or differently, H, F, CN, N(R⁴)₂, a straight-chain, branched or cyclic alkyl, alkoxy or thioalkoxy group having 1 to 40 C atoms, which may be substituted by R⁴ or also unsubstituted, where one or more non-adjacent CH₂ groups may be replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —NR⁵— or —CONR⁵— and where one or more H atoms may be replaced by F, Cl, Br, I, CN, OH or NO₂, or an aromatic or heteroaromatic ring system or an aryloxy or hetero-aryloxy group having 2 to 40 aromatic C atoms, each of which may be substituted by one or more radicals R⁴, or a combination of these systems, such as, for example, a stilbene group, an alkylaryl group or a tolan group; two or more substituents R¹, R² and/or R³ here may define a further mono- or polycyclic, aliphatic or aromatic ring system with one another;
   R⁴ is on each occurrence, identically or differently, H, F, Cl, Br, I, CN, NO₂, a straight-chain, branched or cyclic alkyl or alkoxy chain having 1 to 22 C atoms, in which, in addition, one or more non-adjacent C atoms may be replaced by —R⁵C═CR⁵—, —C≡C—, Si(R⁵)₂, Ge(R⁵)₂, Sn(R⁵)₂, —NR⁵—, —O—, —S—, —CO—O— or —O—CO—O— and where one or more H atoms may be replaced by F, Cl, Br, I, CN or NO₂, or an aryl, heteroaryl or aryloxy group having 1 to 40 C atoms, which, in addition, may be substituted by one or more radicals R⁵, or OH, N(R⁵)₂, B(R⁵)₂ or Si(R⁵)₃;
   R⁵ is on each occurrence, identically or differently, H or an aliphatic or aromatic hydrocarbon radical having 1 to 20 C atoms;
   n is on each occurrence, identically or differently, 1, 2, 3 or 4;
   p is on each occurrence, identically or differently, 1, 2 or 3;
   the dashed bond represents the link to the polymer; it is not intended to denote a methyl group here;
      and
(B) 0.01-95% of at least one covalently bonded iridium complex which emits light from the triplet state, i.e. exhibits phosphorescence instead of fluorescence.

For the purposes of this invention, an aromatic or heteroaromatic ring system is intended to be taken to mean a system which does not necessarily contain only aromatic or heteroaromatic groups, but instead in which a plurality of aromatic or heteroaromatic groups may also be interrupted by a short non-aromatic unit (less than 10% of the atoms other than H, preferably less than 5% of the atoms other than H), such as, for example, sp³-hybridised C, O, N, etc. Thus, for the purposes of this invention, systems such as 9,9′-spirobifluorene, 9,9-diarylfluorene, triarylamine, diaryl ether, etc., for example, are thus also intended to be taken to mean aromatic ring systems. An aromatic ring system here contains at least 6 C atoms, while a heteroaromatic ring system contains at least 2 C atoms and at least one hetero atom, preferably selected from N, O and/or S, and the total number of C atoms and hetero atoms is at least 5.

For the purposes of the present invention, a C₁- to C₄₀-alkyl group, in which, in addition, individual H atoms or CH₂ groups may be substituted by the above-mentioned groups, is particularly preferably taken to mean the radicals methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, n-heptyl, cycloheptyl, n-octyl, cyclooctyl, 2-ethyl-hexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. A C₁- to C₄₀-alkoxy group is particularly preferably taken to mean methoxy, ethoxy, n-propoxy, i-propoxy, n-butoxy, i-butoxy, s-butoxy, t-butoxy or 2-methylbutoxy. A C₂-C₄₀-aryl or -heteroaryl group, which may be monovalent or divalent, depending on the use, and which may also in each case be substituted by the above-mentioned radicals R¹ and linked to the aromatic or heteroaromatic system via any desired positions, is taken to mean, in particular, groups derived from benzene, naphthalene, anthracene, phenanthrene, pyrene, chrysene, perylene, fluoranthene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phen-anthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole. Aromatic ring systems are furthermore taken to mean, in particular, biphenylene, terphenylene, fluorene, spirobifluorene, dihydrophenanthrene, dihydropyrene, tetrahydropyrene or cis- or trans-indeno-fluorene.

The structural unit of the formula (1) may either be bonded into the side chain or into the main chain of the polymer. If X stands for a monovalent group R³, the structural unit of the formula (1) is bonded into the side chain of the polymer. If X stands for a divalent group —(Y)ₚ—, the structural unit of the formula (1) is bonded into the main chain of the polymer.

The copolymer according to the invention may be conjugated, partially conjugated or non-conjugated. It is preferably conjugated or partially conjugated.

For the purposes of this invention, conjugated polymers are polymers which contain in the main chain principally sp²-hybridised (or also sp-hybridised) carbon atoms, which may also be replaced by corresponding hetero atoms. In the simplest case, this means the alternating presence of double and single bonds in the main chain. Principally means that defects occurring naturally (without further assistance) which result in conjugation interruptions do not devalue the term “conjugated polymer”. Furthermore, the term conjugated is likewise used in this application text if arylamine units, arylphosphine units and/or certain heterocyclic units (i.e. conjugation via N, O, S or P atoms) and/or organometallic complexes, such as, for example, iridium complexes (conjugation via the metal atom), are located in the main chain. The term conjugated is likewise used for so-called cr-conjugation, i.e., for example, conjugation via a silicon atom. For the purposes of this invention, partially conjugated polymers are polymers which either contain relatively long conjugated sections interrupted by non-conjugated sections in the main chain or contain relatively long conjugated sections in the side chains of a polymer which is non-conjugated in the main chain. By contrast, units such as, for example, simple alkylene chains, (thio)ether bridges, ester, amide or imide links would clearly be defined as non-conjugated segments.

The copolymers according to the invention may contain various further structural elements in addition to the units of the formula (1) and in addition to the iridium complex. These may be, inter alia, structural units which are able to form the polymer backbone or structural units which influence the charge-injection or charge-transport properties. Units of this type are described in detail, for example, in WO 03/020790 and WO 05/014689.

The copolymers according to the invention may have random, alternating or also block-like structures or also have a plurality of these structures in an alternating arrangement. The polymers may also have a linear, branched or dendritic structure. The use of a plurality of different structural elements enables properties such as, for example, solubility, solid-phase morphology, etc., to be adjusted. The polymers preferably have a linear structure.

The molecular weight. M_{w} of the polymers is between 10³ and 10⁷ g/mol, preferably between 10⁴ and 10⁶ g/mol, particularly preferably between 5·10⁴ and 8·10⁵ g/mol.

The polymers according to the invention are prepared by polymerisation of corresponding monomers, where at least one monomer results in units of the formula (1) in the polymer and at least one monomer contains the iridium complex or a ligand for coordination of iridium. In particular for the synthesis of conjugated polymers, some types which all result in C-C links (SUZUKI coupling, YAMAMOTO coupling, STILLE coupling) have proven successful here. The way in which the polymerisation can be carried out by these methods and the way in which the polymers can then be separated off from the reaction medium and purified are described in detail, for example, in WO 04/037887. A method for the formation of silicon-aryl bonds is described in US 2003/0120124 and consists in the reaction of aryldiazonium salts with substituted chlorosilanes.

The synthesis of partially conjugated or non-conjugated polymers can also be carried out by these methods by using corresponding monomers which are not continuously conjugated. For partially conjugated or non-conjugated polymers, however, other synthetic methods are also suitable, as are generally familiar from polymer chemistry, such as, for example, in general polycondensations or cationic, anionic or free-radical polymerisations, which proceed, for example, via the reaction of alkenes and result in polyethylene derivatives in the broadest sense which contain the functional units (silane units, iridium complexes) bonded in the side chains. In the synthesis of the polymers, it may be preferred for the correspondingly substituted iridium complex to be employed directly as monomer. However, it may also be preferred to employ a correspondingly substituted ligand in the polymerisation reaction and to carry out the complexing of the iridium on the ready-constructed polymer.

In a preferred embodiment of the invention, A is on each occurrence, identically or differently, Si or Ge, particularly preferably Si.

In a further preferred embodiment of the invention, Y is on each occurrence, identically or differently, an aromatic ring system having 2 to 25 C atoms, which may be substituted by one or more radicals R⁴, a vinylene group —CR⁴═CR⁴— or an acetylene group —C≡C—, with the proviso that a vinylene group or an acetylene group may only be bonded to an aromatic system; Y is particularly preferably on each occurrence, identically or differently, an aromatic ring system having 2 to 16 C atoms or spirobifluorene, which may in each case be substituted by one or more radicals R⁴.

In a further preferred embodiment of the invention, R¹, R², R³ are as defined above, where at least one of the substituents R¹ to R³ on each structural unit of the formula (1) represents an aromatic or heteroaromatic ring system having 2 to 25 C atoms, which may be substituted by one or more substituents R⁴; each of the radicals R¹, R² and R³ is particularly preferably on each occurrence, identically or differently, an aromatic or heteroaromatic ring system having 2 to 16 C atoms or spirobifluorene, which may in each case be substituted by one or more substituents R⁴.

In a further preferred embodiment of the invention, the index n, identically or differently on each occurrence, is 1, 2 or 3, particularly preferably 1 or 2.

In a further preferred embodiment of the invention, the index p, identically or differently on each occurrence, is 1 or 3, particularly preferably 1.

Preferred units of the formula (1) furthermore have a symmetrical structure. This preference is due to the relatively easy synthetic accessibility of the compounds. For X=Y (incorporation of the units of the formula (1) into the main chain), it is thus preferred that all Y are selected to be identical and that R¹=R². For X=R³ (incorporation of the units of the formula (1) into the side chain), it is preferred that R¹=R²=R³.

Examples of preferred units of the formula (1) are substituted or unsubstituted structures in accordance with Examples (1) to (27) shown, where the dashed bonds denote a link in the polymer; Examples (1) to (15) here are examples of structural units of the formula (1) which are bonded into the main chain; Examples (16) to (27) are examples of structural units of the formula (1) which are bonded into the side chain. Alkyl stands for a straight-chain, branched or cyclic alkyl chain, which may be substituted or unsubstituted, as defined for R¹, R², R³. For better clarity, potential substituents are generally not shown.

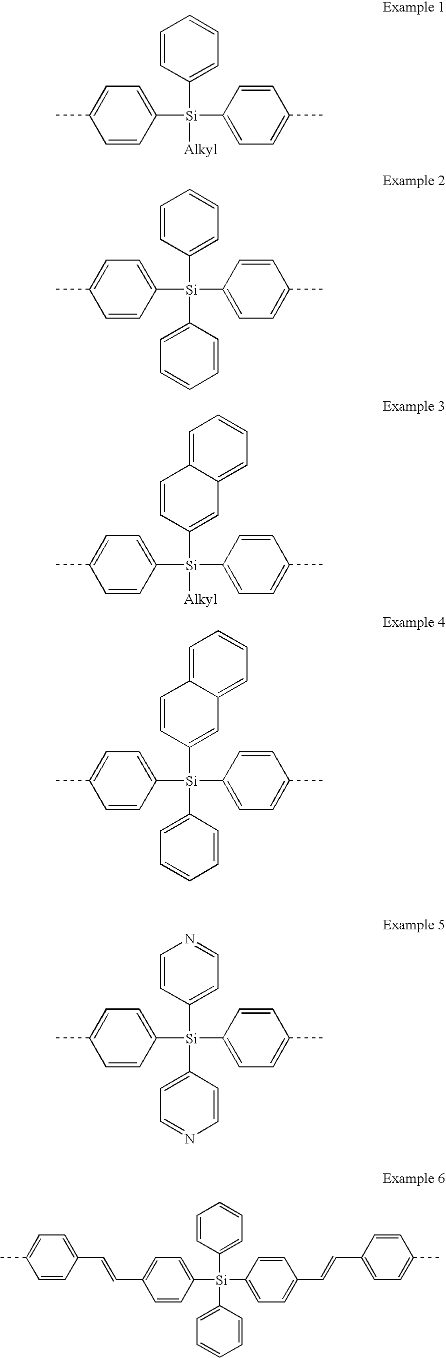

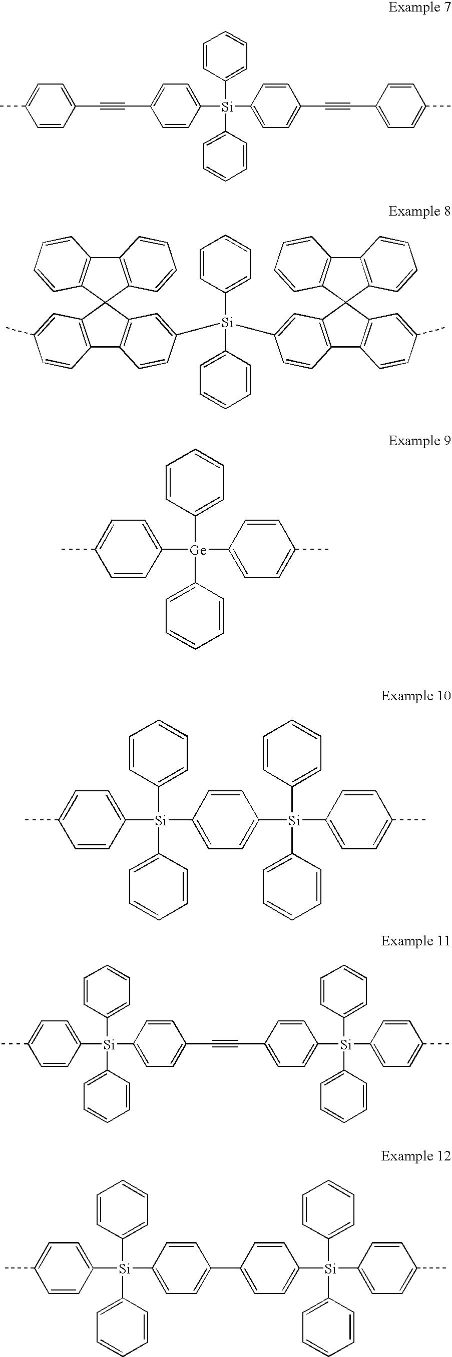

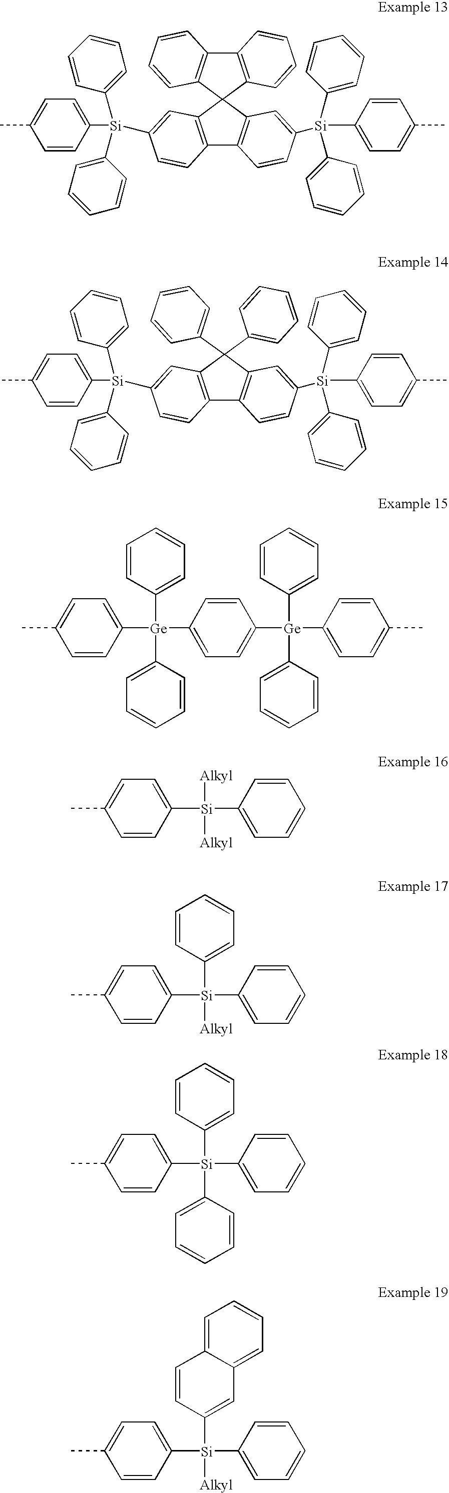

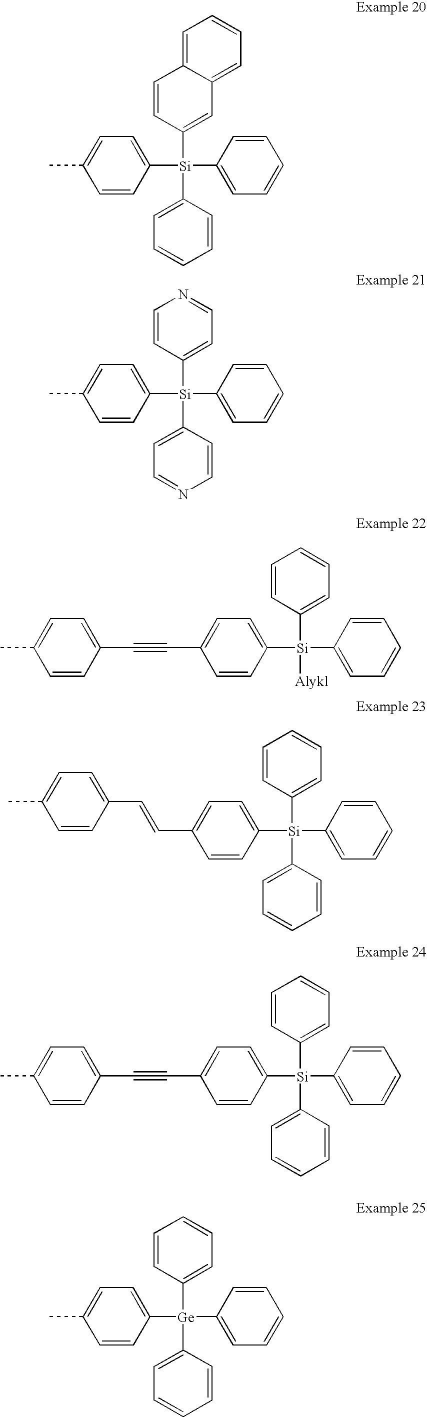

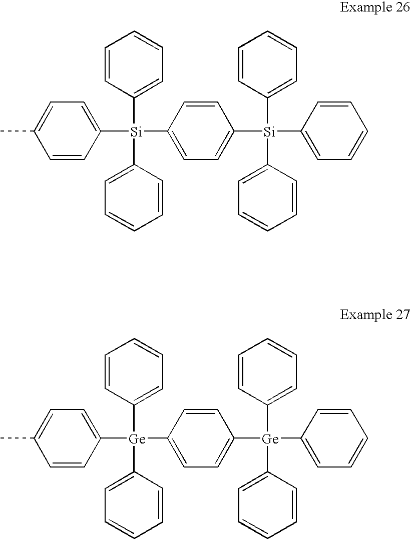

Although this is evident from the description, it should again explicitly be pointed out here that the structural units in accordance with Examples (1) to (27) may also be asymmetrically substituted, i.e. that different substituents R⁴ may be present on a single unit or may also be bonded in different positions. In the case of prochiral structural units, all tacticity possibilities are encompassed.

It has been found that a proportion in the range 1-99.99 mol % of structural units of the formula (1) (based on all recurring units in the polymer) achieves good results. Preference is given to a proportion of 5-80 mol % of recurring units of the formula (1), particular preference is given to a proportion of 10-50 mol % of recurring units of the formula (1).

The iridium complexes bonded in the copolymer are preferably organometallic complexes which are able to emit light from the triplet state at room temperature. Without wishing to be tied to a specific theory, all emitting iridium complexes are referred to as triplet emitters for the purposes of this application. An organometallic compound is intended to be taken to mean a compound which has at least one direct metal-carbon bond. Preference is furthermore given to neutral iridium complexes, in particular neutral iridium(III) complexes.

The iridium complexes preferably contain only chelating ligands, i.e. ligands which coordinate to the iridium via at least two bond sites; particular preference is given to the use of three bidentate ligands, which may be identical or different. The preference for chelating ligands is due to the higher stability of chelate complexes. The iridium complex here preferably has a structure in accordance with formula (2): 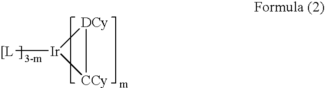
where R⁵ is as defined above, and the following applies to the other symbols used:
DCy is on each occurrence, identically or differently, a cyclic group which contains at least one donor atom, preferably nitrogen or phosphorus, via which the cyclic group is bonded to the iridium and which may in turn carry one or more substituents R⁶; the groups DCy and CCy are bonded to one another via a covalent bond;
CCy is on each occurrence, identically or differently, a cyclic group which contains at least one carbon atom via which the cyclic group is bonded to the iridium and which may in turn carry one or more substituents R⁶;
L is on each occurrence, identically or differently, a bidentate chelating ligand;
R is on each occurrence, identically or differently, H, F, Cl, Br, I, NO₂, CN, a straight-chain or branched or cyclic alkyl or alkoxy group having 1 to 40 C atoms, where one or more non-adjacent CH₂ groups may be replaced by C═O, C═S, C═Se, C═NR⁵, —R⁵C═CR⁵—, —C═C—, —O—, —S—, —NR⁵—, Si(R⁵)₂ or —CONR⁵— and where one or more H atoms may be replaced by F, Cl, Br, I, CN or NO₂, or an aromatic or heteroaromatic ring system having 2 to 40 C atoms, which may be substituted by one or more non-aromatic radicals R⁶; a plurality of substituents R⁶ here, both on the same ring and also on the two different rings, may together in turn define a further mono- or polycyclic, aliphatic or aromatic ring system;
   m is on each occurrence 1, 2 or 3, preferably 2 or 3, particularly preferably 3; the linking to the polymer takes place here either via one or via a plurality of ligands, preferably via one or two ligands.

Preferred ligands L are monoanionic ligands, such as 1,3-diketonates derived from 1,3-diketones, such as, for example, acetylacetone, benzoylacetone, 1,5-diphenylacetylacetone, dibenzoylmethane, bis(1,1,1-trifluoroacetyl)methane, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, dimethylglycine, alanine, dimethylaminoalanine, or salicyliminates derived from salicylimines, such as, for example, methylsalicylimine, ethylsalicylimine, phenylsalicylimine.

Preference is likewise given to polynuclear iridium complexes and iridium clusters.

The iridium complex is incorporated covalently into the polymer chain. In order to facilitate incorporation of the complex into the polymer, functional polymerisable groups must be present on the complex. Examples of corresponding brominated complexes which can be employed as monomers in polycondensation reactions (for example in accordance with SUZUKI or in accordance with YAMAMOTO) are described in WO 02/068435 and in the unpublished application DE 10350606.3.

It has been found that a proportion of 0.01-95 mol %, preferably 0.1-80 mol %, particularly preferably 0.5-50 mol %, in particular 1-25 mol %, of the iridium complex exhibits good results, where the data relate to the total number of recurring units present in the polymer.

It may also be preferred to admix further conjugated, partially conjugated or non-conjugated polymers, oligomers, dendrimers or further low-molecular-weight compounds with the polymer. The addition of further components may prove sensible for some applications: thus, hole or electron injection or hole or electron transport in the corresponding blend can be regulated, for example, by addition of an electronically active substance. The added component may also improve singlet-triplet transfer or itself emit light. However, the addition of electronically inert compounds may also be helpful in order, for example, to control the viscosity of a solution or the morphology of the film formed. The invention likewise relates to the blends obtained in this way. The copolymers according to the invention have the following surprising advantages over the prior art:
The efficiency of light emission by the iridium complex is better in copolymers according to the invention compared with copolymers and mixtures in accordance with the prior art.
The operating voltages of the OLEDs are lowered compared with the prior art.
Good results are obtained with a wide range of different red and green triplet emitters. This is a surprising result since it has hitherto always been necessary to optimise the combination of certain triplet emitters with certain matrix materials individually.
The polymers are very readily soluble and can therefore also be processed very well from solution.

The invention furthermore relates to solutions and formulations of one or more copolymers or blends according to the invention in one or more solvents. The way in which polymer solutions can be prepared is described, for example, in WO 02/072714, in WO 03/019694 and in the literature cited therein. These solutions can be used to produce thin polymer layers, for example by area-coating processes (for example spin coating) or printing processes (for example ink-jet printing).

The copolymers according to the invention can be used in PLEDs, in particular as electroluminescent materials (=emitting materials). For the construction of PLEDs, use is generally made of a general process, which should be adapted correspondingly for the individual case. A process of this type has been described in detail, for example, in WO 04/037887.

The invention therefore also relates to the use of a copolymer according to the invention as electroluminescent material in a PLED.

The invention likewise relates to a PLED having one or more layers, where at least one of these layers comprises at least one copolymer according to the invention.

The present application text and the examples below are directed to the use of copolymers according to the invention in relation to PLEDs and the corresponding displays. In spite of this restriction of the description, it is possible for the person skilled in the art, without further inventive step, also to use the polymers according to the invention for further uses in other electronic devices, for example for organic solar cells (O—SCs), non-linear optics, frequency doubling (up conversion), organic optical detectors, organic field-quench devices (O-FQDs) or also organic laser diodes (O-lasers), to mention but a few applications. The present invention also relates to these.

The invention is explained in greater detail by the examples below, without wishing to be restricted thereby.

### EXAMPLES

### Example 1

### Synthesis of 4,4′-dibromotetraphenylsilane (monomer Si1)

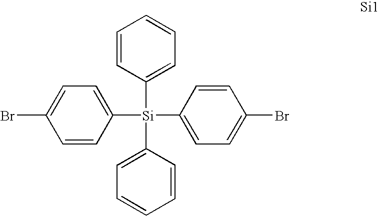

33.9 g (144 mmol) of 1,4-dibromobenzene were dissolved in 300 ml of absolute THF in a 1000 ml four-necked flask with internal thermometer, stirrer bar, argon blanket and dropping funnel which had been dried by heating, and cooled to −75° C. 90 ml (144 mmol) of n-butyllithium (1.6M in hexane fraction) were added dropwise over the course of 30 minutes, and the mixture was subsequently stirred at this temperature for 1 h. 15.3 ml (18.3 g, 72 mmol) of diphenyldichlorosilane in 60 ml of THF were then added dropwise at −75° C., and the mixture was warmed to room temperature overnight. The solvent was removed, and the residue was suspended in dichloromethane and filtered. The solvent was removed from the filtrate, and the product was recrystallised twice from butanol and twice from heptane/toluene, giving 16.8 g (47% of theory) in a purity of 99.9% according to HPLC.

¹H-NMR (CDCl₃): [ppm]=7.51 (m, 8H), 7.55 (t, ³J_{HH}=7.7 Hz, 2H), 7.38 (m, 8H).

### Example 2

### Synthesis of the Iridium Monomers

The synthesis of the iridium monomers used is described in the unpublished application DE 10350606.3. Iridium monomers Ir1 and Ir2 used below are depicted again here for clarity:

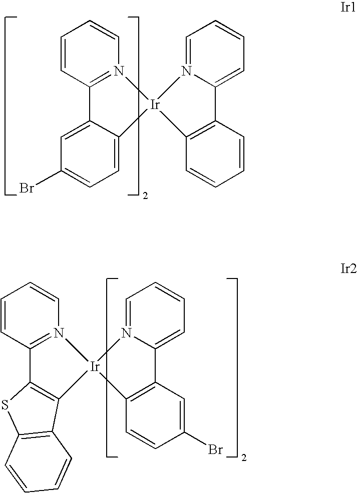

### Example 3

### Synthesis of Further Comonomers

The synthesis of the further comonomers used is described in detail in WO 02/077060 and the literature cited therein. Monomer M1 used below is depicted again here for clarity:

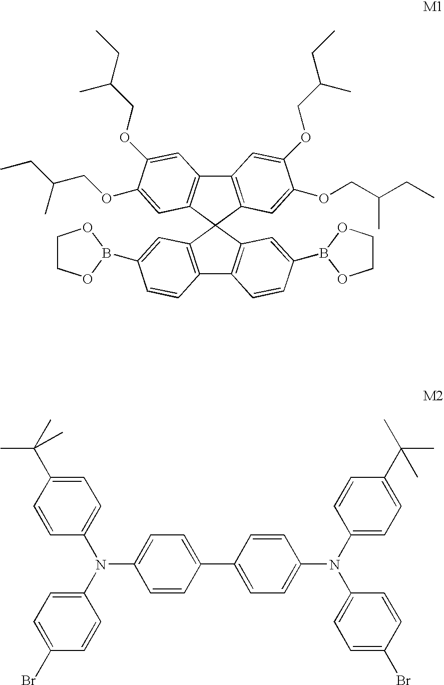

### Example 4:0

### Synthesis of copolymer P1 according to the invention

1.601 g of M1, 0.889 g of Si1, 0.162 g of Ir1 and 2.010 g of K₃PO₄—H₂O were degassed for 30 min at 40° C. in 25 ml of a mixture of dioxane and toluene (3:1), subsequently heated to 95° C., and 0.5 ml of a 0.05% solution of Pd(OAc)₂ and P(o-Tol)₃ was added. After 6 h under reflux, the mixture was cooled to 65° C. and stirred for 4 h with 10 ml of N,N-diethyldithiocarbamide solution. After phase separation, the organic phase washed with water. The polymer was precipitated by dropwise addition into twice the amount of methanol and dissolved in toluene. After filtration through Celite, the polymer was again precipitated using methanol and dried under reduced pressure. The yield was 1.29 g (60% of theory), the molecular weight. Mₙ=29,000 g/mol and M_{w}=177,000 g/mol (GPC in THF with polystyrene standard).

Further polymers according to the invention (polymers P2, P3 and P4) were prepared as described for the synthesis of polymer P1.

### Example 5

### Production of Polymeric Light-Emitting Diodes (PLEDs)

The way in which PLEDs can be produced is described in detail in WO 04/037887 and the literature cited therein.

### Examples 6 to 9

### Device Examples

All polymers prepared were also investigated in PLEDs. The composition of the polymers and the results in electroluminescence (measured at room temperature, 25° C.) are summarised in Table 1.

TABLE 1
Some device results with copolymers according to the invention

| | | | | | | | | Lifetime |
|---|---|---|---|---|---|---|---|---|
| Example | Polymer | Si monomer | Ir monomer | Other monomers | Max. eff./cd/A | U @100 cd/m²/V | CIE x/y^{a} | (100)^{b} |
| Example 6 | P1 | 45% Si1 | 5% Ir1 | 50% M1 | 7.2 | 9.9 | 0.51/0.48 | 7 hrs |
| Example 7 | P2 | 45% Si1 | 5% Ir2 | 50% M1 | 7.7 | 7.2 | 0.60/0.40 | 65 hrs |
| Example 8 | P3 | 49% Si1 | 1% Ir2 | 50% M1 | 4.8 | 8.4 | 0.61/0.39 | 42 hrs |
| Example 9 | P4 | 35% Si1 | 5% Ir2 | 50% M1, | 3.7 | 6.5 | 0.60/0.39 | 41 hrs |
| | | | | 10% M2 | | | | |

^{a}CIE coordinates: chromaticity coordinates of the Commission Internationale de I'Eclairage from 1931
^{b}The lifetime was extrapolated to a uniform initial luminous density of 100 cd/m² using an acceleration factor of 2.

1. Copolymers comprising:
A) 1-99.99 mol % of at least one structural unit of the formula (1) 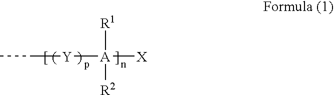
A is on each occurrence, identically or differently, Si, Ge, Sn or Pb;
Y is on each occurrence, identically or differently, a divalent aromatic or heteroaromatic ring system having 1 to 40 C atoms, which is optionally substituted by one or more radicals R⁴, a vinylene group —CR⁴═CR⁴— or an acetylene group —C≡C—;
X is on each occurrence, identically or differently, a divalent group —(Y)ₚ— or a monovalent group R³;
R¹, R² and R³ are on each occurrence, identically or differently, H, F, CN, N(R⁴)₂, a straight-chain, branched or cyclic alkyl, alkoxy or thioalkoxy group having 1 to 40 C atoms, which are optionally substituted by R⁴ or unsubstituted, wherein one or more non-adjacent CH₂ groups are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —NR⁵— or —CONR⁵— and wherein one or more H atoms are opionally replaced by F, Cl, Br, I, CN, OH or NO₂, or an aromatic or heteroaromatic ring system or an aryloxy or heteroaryloxy group, each having up to 40 aromatic C atoms, each of which is optionally substituted by one or more radicals R⁴, or a combination of these systems; and wherein two or more substituents R¹, R² and/or R³ optionally define a further mono- or polycyclic, aliphatic or aromatic ring system with one another;
R⁴ is on each occurrence, identically or differently, H, F, Cl, Br, I, CN, NO₂, a straight-chain, branched or cyclic alkyl or alkoxy chain having 1 to 22 C atoms, wherein one or more non-adjacent C atoms are optionally replaced by —R⁵C═CR⁵—, —C≡C—, Si(R⁵)₂, Ge(R⁵)₂, Sn(R⁵)₂, —NR⁵—, —O—, —S—, —CO—O— or —O—CO—O— and where one or more H atoms are optionally replaced by F, Cl, Br, I, CN or NO₂, an aryl, heteroaryl or aryloxy group having 1 to 40 C atoms, which are optionally substituted by one or more radicals R⁵, or OH, N(R⁵)₂, B(R⁵)₂ or Si(R⁵)₃;
R⁵ is on each occurrence, identically or differently, H or an aliphatic or aromatic hydrocarbon radical having up to 20 C atoms;
n is on each occurrence, identically or differently, 1, 2, 3 or 4;
p is on each occurrence, identically or differently, 1, 2 or 3;
and wherein the dashed bond represents the link to the polymer; and
B) 0.01-95 mol % of at least one covalently bonded iridium complex which emits light from the triplet state.

2. Copolymers according to claim 1, wherein X is a monovalent group R³, and the structural unit of the formula (1) is bonded to the side chain of the polymer.

3. Copolymers according to claim 1, wherein X is a divalent group —(Y)ₚ—, and the structural unit of the formula (1) is bonded to the main chain of the polymer via —(Y)ₚ—.

4. Copolymers according to claim 1, wherein the iridium complex is incorporated into the side chain of the polymer.

5. Copolymers according to claim 1, wherein the iridium complex is incorporated into the main chain of the polymer.

6. Copolymers according to claim 1, wherein it is conjugated or partially conjugated.

7. Copolymers according to claim 1, wherein said copolymers further comprise structural elements in addition to units of the formula (1) and in addition to the iridium complex.

8. Copolymers according to claim 7, wherein the further structural units form the polymer backbone and/or improve the charge-injection or charge-transport properties.

9. Copolymers according to claim 1, wherein A, identically or differently on each occurrence, is Si or Ge.

10. Copolymers according to claim 1, wherein Y, identically or differently on each occurrence, is an aromatic ring system having up to 25 C atoms, which are optionally substituted by one or more radicals R⁴, a vinylene group —CR⁴═CR⁴— or an acetylene group —C≡C—, with the proviso that a vinylene group or an acetylene group are only bonded to an aromatic system.

11. Copolymers according to claim 1, wherein at least one of R¹, R², R³, identically or differently on each occurrence, is an aromatic or heteroaromatic ring system having up to 25 C atoms, which are optionally substituted by one or more substituents R⁴.

12. Copolymers according to claim 1, wherein n, identically or differently on each occurrence, is 1, 2 or 3.

13. Copolymers according to claim 1, wherein p, identically or differently on each occurrence, is 1 or 3.

14. Copolymers according to claim 1, wherein the structural units of the formula (1) have a symmetrical structure.

15. Copolymers according to claim 1, wherein the structural units of the formula (1) are selected from example structures (1) to (27), which are optionally substituted or unsubstituted

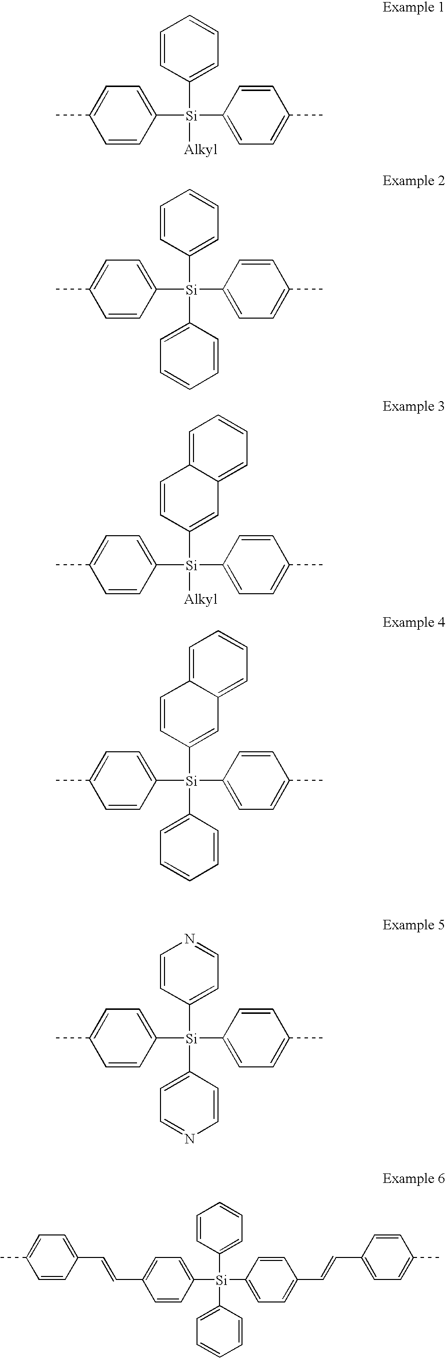

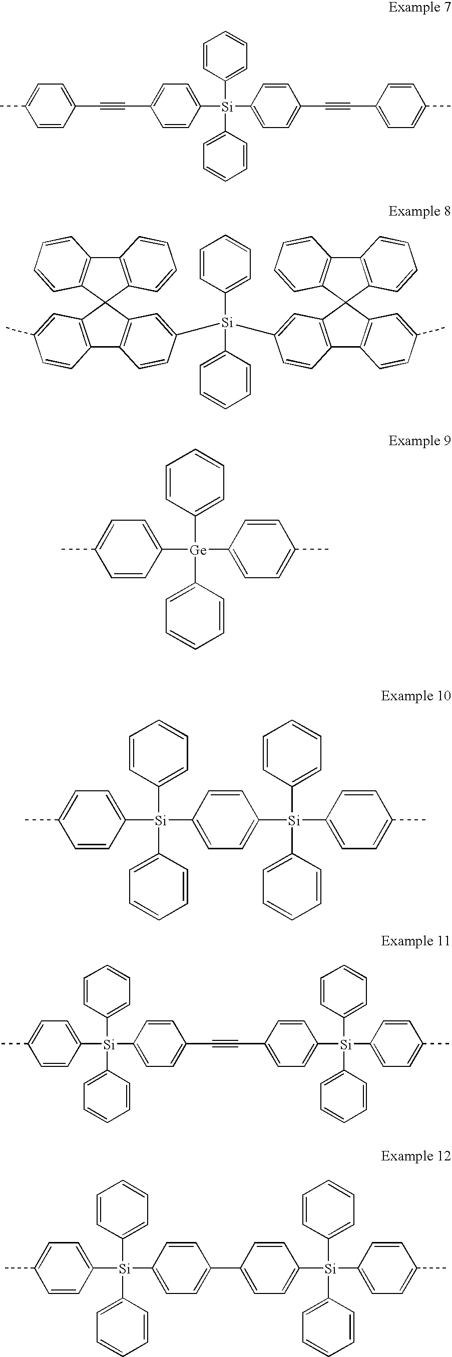

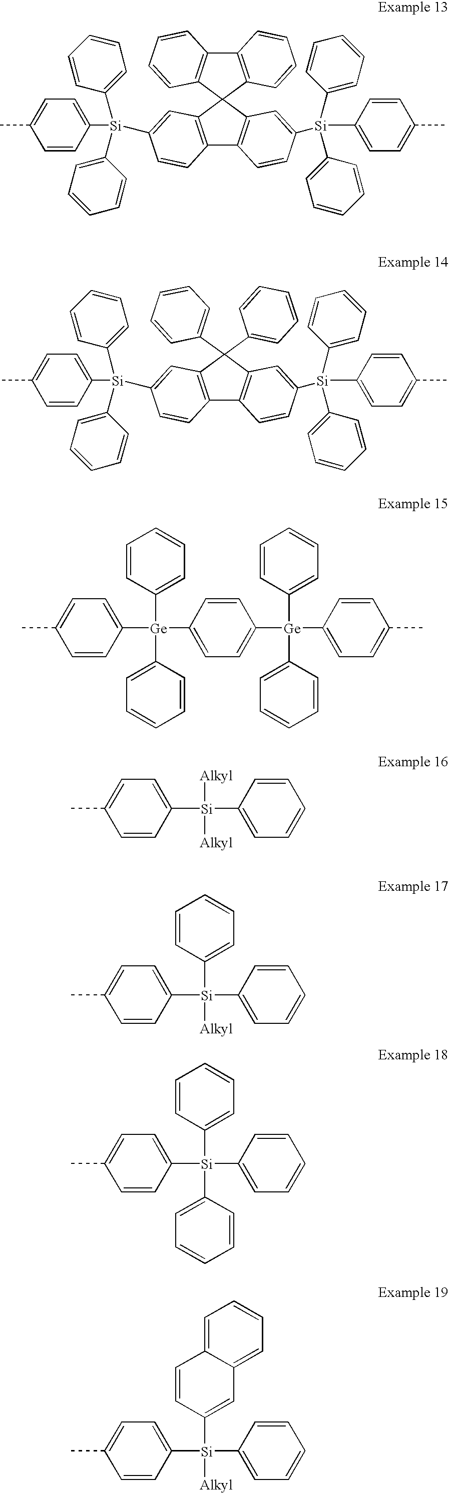

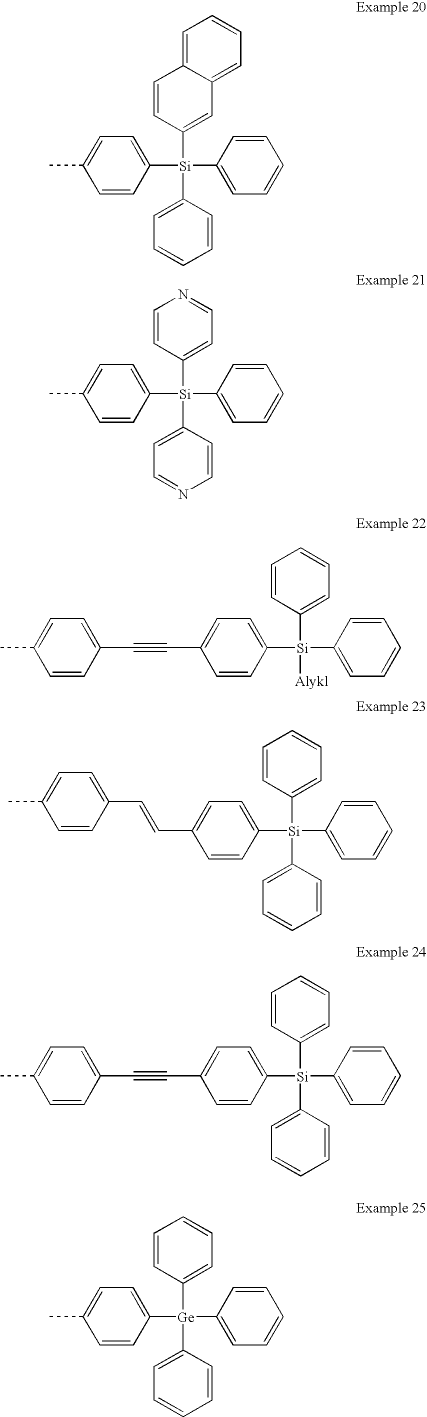

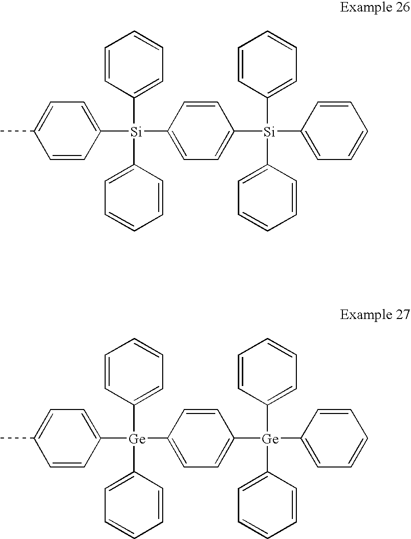

16. Copolymers according to claim 1, wherein they comprise 5-80 mol % of structural units of the formula (1).

17. Copolymers according to claim 1, wherein they are organometallic iridium complexes.

18. Copolymers according to claim 1, wherein the iridium complexes contain three ligands which chelate in a bidentate manner.

19. Copolymers according to claims 17 wherein the iridium complexes have a structure of formula (2): 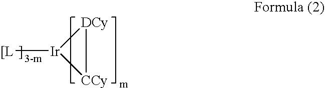
wherein:
DCy is on each occurrence, identically or differently, a cyclic group comprising at least one donor atom via which the cyclic group is bonded to the iridium and which is optionally substituted with one or more substituents R⁶; and wherein the groups DCy and CCy are bonded to one another via a covalent bond;
CCy is on each occurrence, identically or differently, a cyclic group comprising at least one carbon atom via which the cyclic group is bonded to the iridium and which is optionally substituted with one or more substituents R⁶;
L is on each occurrence, identically or differently, a bidentate chelating ligand;
R⁶ is on each occurrence, identically or differently, H, F, Cl, Br, I, NO₂, CN, a straight-chain or branched or cyclic alkyl or alkoxy group having up to 40 C atoms, wherein one or more non-adjacent CH₂ groups optionally replaced by C═O, C═S, C═Se, C═NR⁵, —R⁵C═CR⁵—, —C≡C—, —O—, —S—, —NR⁵—, Si(R⁵)₂ or —CONR⁵— and wee wherein one or more H atoms may be optionally replaced by F, Cl, Br, I, CN or NO₂, or an aromatic or heteroaromatic ring system having up to 40 C atoms, which are optionally substituted by one or more non-aromatic radicals R⁶; wherein a plurality of substituents R⁶, on the same ring and/or on two different rings optionally define a further mono- or polycyclic, aliphatic or aromatic ring system;
m is on each occurrence 1, 2 or 3; and wherein
the linking to the polymer is via one or via a plurality of ligands.

20. Copolymers according to claim 19, wherein L is a monoanionic ligand selected from the group consisting of the 1,3-diketonates derived from 1,3-diketones, 3-ketonates derived from 3-ketoesters, carboxylates derived from aminocarboxylic acids or salicyliminates derived from salicylimines.

21. Copolymers according to claim 1, wherein the proportion of the iridium complexes in the polymer is 0.1-80 mol %.

22. Mixtures of at least one copolymer according to claim 1 with one or more conjugated, partially conjugated or non-conjugated polymers, oligomers, dendrimers or low-molecular-weight compounds.

23. (canceled)

24. Organic electronic device having one or more layers, wherein at least one of these layers comprises at least one copolymer according to claim 1.

25. Organic electronic device according to claim 24, wherein said device is an organic light-emitting diode, organic solar cell, non-linear optical device, frequency doubling (up conversion), organic optical detector, organic field-quench device or organic laser diode.

26. Copolymers according to claim 19, wherein the at least one donor atom of the cyclic group DCy is nitrogen or phosphorus.

27. An organic electronic device comprising at least one copolymer according to claim 1.
